(19) United States
(12) Patent Application Publication
(10) Pub. No.: US 2009/0323406 A1
(43) Pub. Date: Dec. 31, 2009

(54) MAGNETIC MEMORY ELEMENT, AND METHOD OF MANUFACTURING MEMORY ELEMENT

(75) Inventors: Takao Ochiai, Kawasaki (JP); Hiroshi Ashida, Kawasaki (JP); Keiichi Nagasaka, Kawasaki (JP)

Correspondence Address: GREER, BURNS & CRAIN, 300 S WACKER DR, 25TH FLOOR, CHICAGO, IL, 60606, US

(73) Assignee: FUJITSU LIMITED, Kawasaki-shi (JP)

(21) Appl. No.: 12/404,781

(22) Filed: Mar. 16, 2009

(30) Foreign Application Priority Data
Jun. 30, 2008 (JP) 2008-171137

(51) Int. Cl. G11C 11/00; H01L 21/00; G11C 11/14

(52) U.S. Cl. 365/158; 438/3; 365/171; 257/E21.001

(57) ABSTRACT

A magnetic memory element includes an impurity element, and magnetic thin lines to which the impurity element is added to adjust the movement of a magnetic domain wall in a magnetic field. Applying a voltage to the magnetic thin lines controls a position of the magnetic domain wall to invert a magnetization direction of a magnetic recording layer adjacent to the magnetic domain wall, by which information is recorded.

### CROSS-REFERENCE TO RELATED APPLICATION

This application is based upon and claims the benefit of priority of the prior Japanese Patent Application No. 2008-171137, filed on Jun. 30, 2008, the entire contents of which are incorporated herein by reference.

### FIELD

The embodiments discussed herein are directed to a magnetic memory element, a magnetic memory device, and a method of manufacturing a memory element.

### BACKGROUND

Recently, research and development of next-generation extremely-large-storage nonvolatile memory as an alternative to the current dynamic random access memory (DRAM) and flash memory are actively performed. As candidates of the extremely-large-storage nonvolatile memory, there are ferroelectric random-access memory (FeRAM), phase-change RAM (PRAM) using a phase change of insulators constituting a memory, magnetoresistive random-access memory (MRAM) using a tunneling magnetoresistive (TMR) effect, and resistance random-access memory (RRAM) using a huge resistance change generated by an application direction of a pulse current.

However, because performances of these memory devices have both advantages and disadvantages, these memory devices have not yet taken over the current memory devices.

Meanwhile, recently, a concept called a racetrack memory attempting to achieve a large-storage memory using a magnetic-domain-wall motion phenomenon by spin implantation (see A. Yamaguchi et al., Phys. Rev. Lett., 92, 077205 (2004)) and the TMR effect has been proposed (see U.S. Pat. No. 6,834,005 B1., Parkin (IBM)). Other storage memories using the magnetic-domain-wall motion phenomenon and the TMR effect have also been studied (for example, see Japanese Laid-open Patent Publication No. 2007-324269, Japanese Laid-open Patent Publication No. 2007-324172, and Japanese Laid-open Patent Publication No. 2007-317895).

A conventional magnetic-domain-wall-motion storage device has recorded information by controlling positions of magnetic domain walls by processing shapes of magnetic-metal thin lines such as notches (see M. Hayashi et al., Phys. Rev. Lett., 97, 207205 (2006)), zig-zag shapes (see Y. Togawa et al., J. J. Appl. Phys., 45, L683-L685 (2006)), latchets (see A. Himeno et al., Appl. Phys. Lett., 87, 243108 (2005)), and step structures (see Intermag 2008, Digest p. 1268/Gt-18. Current induced domain wall motion with step structure), to control positions of the magnetic domain walls.

However, when voltage pulses are continuously applied to the magnetic-metal thin lines to control positions of magnetic domain walls in the magnetic-domain-wall-motion storage device, plural magnetic domain walls are generated at notch portions where magnetic domain walls are not basically present (for example, a part where current density of the magnetic-metal thin lines increases). Due to the influence of the magnetic domain walls, unpredicted magnetization inversion occurs. Such unpredicted occurrence of magnetization inversion is a serious problem in the memory operation of elements.

### SUMMARY

According to an aspect of the invention, a magnetic memory element includes an impurity element; and magnetic thin lines to which the impurity element is added to adjust the movement of a magnetic domain wall in a magnetic field, wherein applying a voltage to the magnetic thin lines controls a position of the magnetic domain wall to invert a magnetization direction of a magnetic recording layer adjacent to the magnetic domain wall, by which information is recorded.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWING

FIG. 1 depicts an SEM image of a NiFe thin line having notches introduced at equal intervals;

FIG. 2 depicts a MEM image of a NiFe thin line applied with a voltage pulse;

FIG. 3 is a schematic diagram for explaining a problem of a conventional magnetic-domain-wall-motion storage device;

FIG. 4 is a schematic diagram for explaining easiness for a magnetic domain wall to move when an impurity Pt is added to NiFe;

FIG. 5 is a schematic diagram of a circuit used to measure a magnetic-domain-wall motion probability;

FIG. 6 is a graph of a measurement result of the magnetic-domain-wall motion probability;

FIG. 7 is a graph of a relationship between saturation magnetization (Ms) and a magnetic holding force (Hc) of a NiFe thin film and those of a NiFePt thin film;

FIG. 8 depicts a method of manufacturing a magnetic-domain-wall-motion storage device according to an embodiment of the present invention; and

FIG. 9 depicts another method of manufacturing the magnetic-domain-wall-motion storage device according to the embodiment.

### DESCRIPTION OF EMBODIMENT

Preferred embodiments of the present invention will be explained with reference to the accompanying drawings.

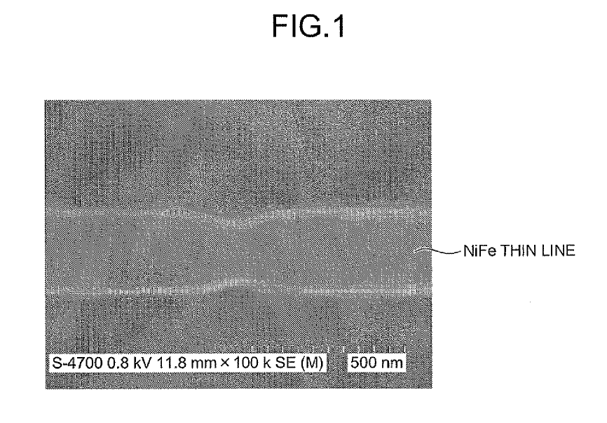

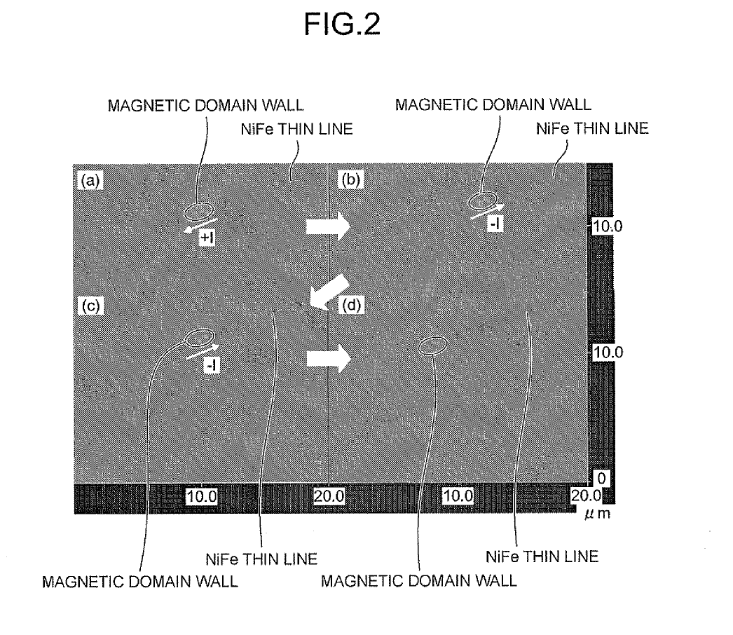

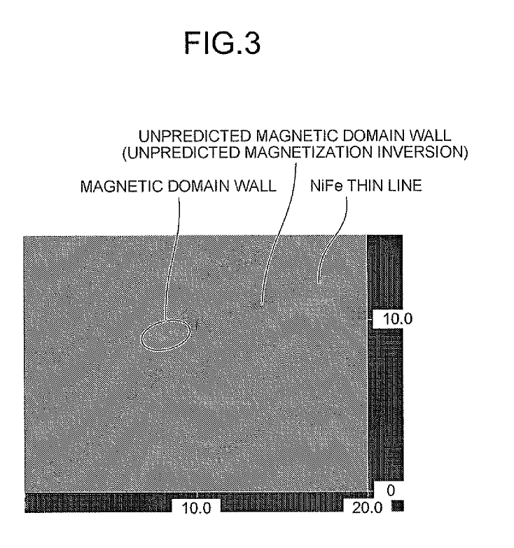

A magnetic-metal thin line used in a magnetic-domain-wall-motion storage device is explained first. One example of the magnetic-metal thin line according to an embodiment of the present invention is explained using a Ni₈₀Fe₂₀ (hereinafter, simply “NiFe”) thin line. FIG. 1 depicts a scanning electron microscope (SEM) image of a NiFe thin line having notches introduced at equal intervals. FIG. 2 depicts a magnetic force microscope (MEM) image of a NiFe thin line applied with a voltage pulse. FIG. 3 is a schematic diagram for explaining a problem of a conventional magnetic-domain-wall-motion storage device.

When a voltage pulse is applied to a NiFe thin line illustrated in FIG. 1, a position of a magnetic domain wall in the NiFe thin line can be controlled. When the magnetic domain wall in the NiFe thin line moves, a magnetization direction of a longitudinal direction (a direction longitudinal to the NiFe thin line) of a magnetic recording layer adjacent to the moved magnetic domain wall changes to a magnetic domain wall side. The magnetic-domain-wall-motion storage device stores information based on this magnetization direction.

As illustrated in FIG. 2, when a voltage is applied to a NiFe thin line, head-to-head magnetic domain walls move to a direction opposite to a direction of a current flowing due to the application of the voltage (a direction in which an electron spin flows). Conventionally, a configuration of a NiFe thin line is changed to adjust a motion distance of the magnetic domain wall when a voltage pulse is applied to the NiFe thin line. In a region having a large cross section of a NiFe thin line, for example, a magnetic domain wall can move easily. In a region having a small cross section of a NiFe thin line, or in a region having a curved NiFe thin line, a magnetic domain wall cannot move easily.

However, as illustrated in FIG. 3, when the same voltage is continuously applied to a NiFe thin line, plural magnetic domain walls are generated in a notch part where a magnetic domain wall is not basically present (for example, a part where a cross section of a NiFe thin line becomes small, and current density increases). Due to the influence of this magnetic domain wall, magnetization inversion occurs unpredictably.

Characteristics of the magnetic-domain-wall-motion storage device according to the present embodiment are explained next. A magnetic-metal thin line (a NiFe thin line) of the magnetic-domain-wall-motion storage device is manufactured by adding an impurity element (for example, an element in which the magnetic holding force of magnetic-metal thin lines is modulated (changed), such as platinum (Pt), iridium (Ir), ruthenium (Ru)) to a ferromagnetic metal (NiFe). With this arrangement, easiness for the magnetic domain wall to move in a magnetic field in the magnetic-metal thin line (a depinning magnetic field of the magnetic domain wall) is adjusted. In the present embodiment, addition of an impurity element Pt to NiFe is explained as one example.

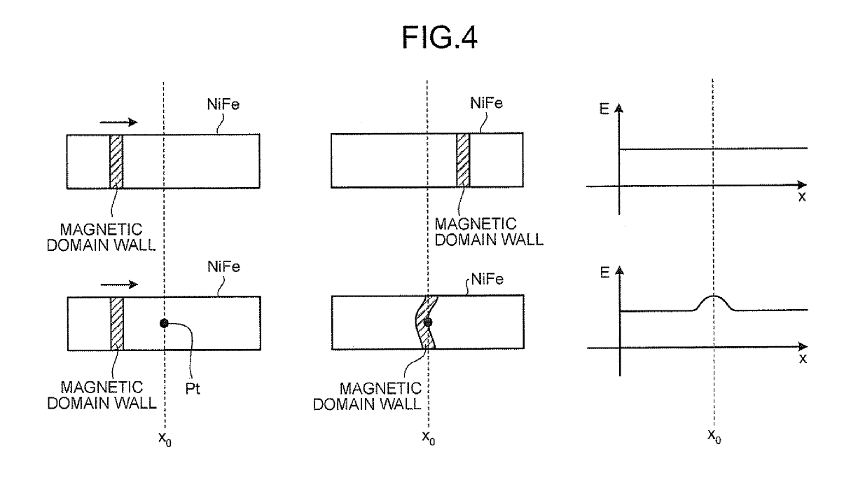

FIG. 4 is a schematic diagram for explaining easiness for a magnetic domain wall to move when an impurity Pt is added to NiFe. As illustrated in the upper row in FIG. 4, when an impurity Pt is not added to NiFe, the energy required by the magnetic domain wall motion becomes constant. Therefore, the magnetic domain wall can move easily.

On the other hand, as illustrated in the lower row in FIG. 4, when an impurity Pt is added to NiFe, the magnetic domain wall motion is interrupted by the impurity Pt. Therefore, the energy required by the magnetic domain wall motion becomes large (the magnetic domain wall cannot move easily) at a position where the impurity Pt is present. When the impurity Pt is present at a position of x₀, for example, energy required for the impurity Pt to pass the position x₀ becomes larger than energy required to pass other positions.

As explained above, the magnetic-domain-wall-motion storage device according to the present embodiment adjusts easiness for the magnetic domain wall to move in the magnetic-metal thin line by adding an impurity element to the ferromagnetic metal. Therefore, a shape of the magnetic-metal thin line is not required to be moved as required by the conventional practice, and unpredicted occurrence of magnetization inversion can be prevented. Other configurations of the magnetic-domain-wall-motion storage device are identical to those of the conventional magnetic-domain-wall-motion storage device. That is, the magnetic-domain-wall-motion storage device controls a moving position of the magnetic domain wall by applying a voltage to the magnetic-metal thin line, and stores information by changing a magnetization direction of the magnetic recording layer adjacent to the magnetic domain wall.

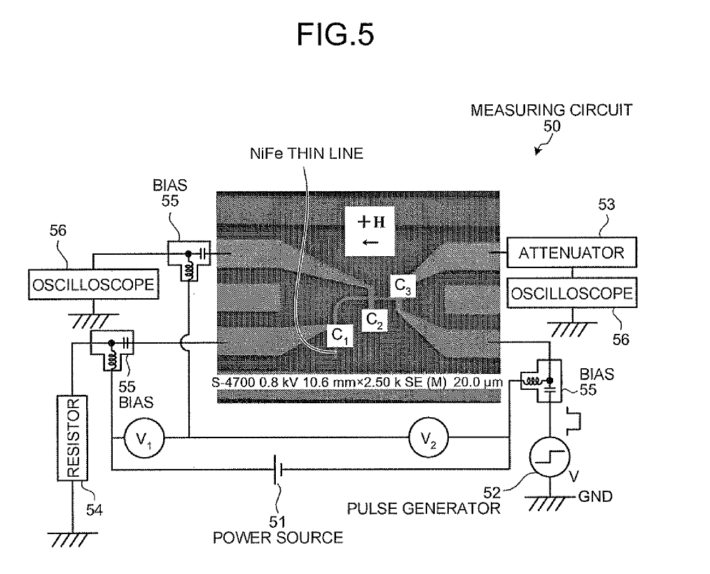

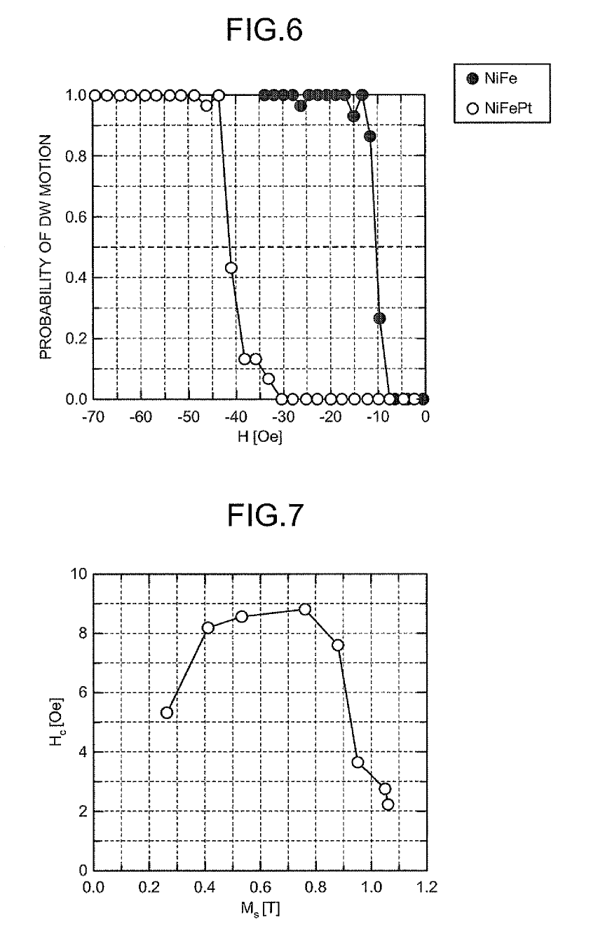

A magnetic-domain-wall motion probability of a magnetic-metal thin line (a NiFe thin line) according to the present embodiment is explained next. FIG. 5 is a schematic diagram of a measuring circuit used to measure a magnetic-domain-wall motion probability, and FIG. 6 is a graph of a measurement result of the magnetic-domain-wall motion probability.

As illustrated in FIG. 5, a measuring circuit 50 includes a power source 51, a pulse generator 52, an attenuator 53, a resistor 54, a bias 55, and an oscilloscope 56. A voltage pulse output from the pulse generator 52 is applied to a NiFe thin line (a NiFe thin line containing an impurity Pt, or a NiFe thin line not containing an impurity Pt). The measuring circuit 50 measures a probability that a magnetic domain wall generated between C₂ and C₃ by the pulse generator 52 moves between C₁ and C₂.

In the measurement of the measuring circuit 50, calculation of a motion probability is performed by measuring each parameter (a magnetic field H (Oe) to be applied, and a NiFe thin line to be applied with the magnetic field) at 50 times. A depinning magnetic field is defined as a magnetic field having a motion probability as 50%.

As the result of measurement performed by the measuring circuit 50 is referenced, it is clear that in a NiFe (saturation magnetization Ms=1.06 T) thin line, a probability that a magnetic domain wall moves to C₁ and C₂ due to a magnetic field of H=10 Oe becomes high, and that in a NiFePt (saturation magnetization Ms=0.76 T) thin line added with Pt, a probability that a magnetic domain wall moves to C₁ and C₂ due to a magnetic field of H=40 Oe becomes high. That is, a depinning magnetic field of the NiFePt thin line is about four times the depinning magnetic field of the NiFe thin line.

A relationship between saturation magnetization (Ms) and a magnetic holding force (Hc) of a NiFe thin film and those of a NiFePt thin film is explained next. FIG. 7 is a graph of a relationship between the saturation magnetization (Ms) and a magnetic holding force (Hc) of a NiFe thin film and those of a NiFePt thin film.

As illustrated in FIG. 7, Hc of NiFePt (Ms=0.76 T) in a thin film state is about four times that of NiFe (Ms=1.06 T), and processed samples of thin lines (a NiFe thin line, and a NiFe thin line added with an impurity Pt) also have a similar size relationship. This is because the added impurity Pt works as a barrier wall interrupting the magnetic domain wall motion, as explained with reference to FIG. 4. This means that when a nonmagnetic element (such as Pt, Ir, and W) is locally added to a NiFe thin line, a position of the magnetic domain wall can be controlled without changing a configuration of the NiFe thin line.

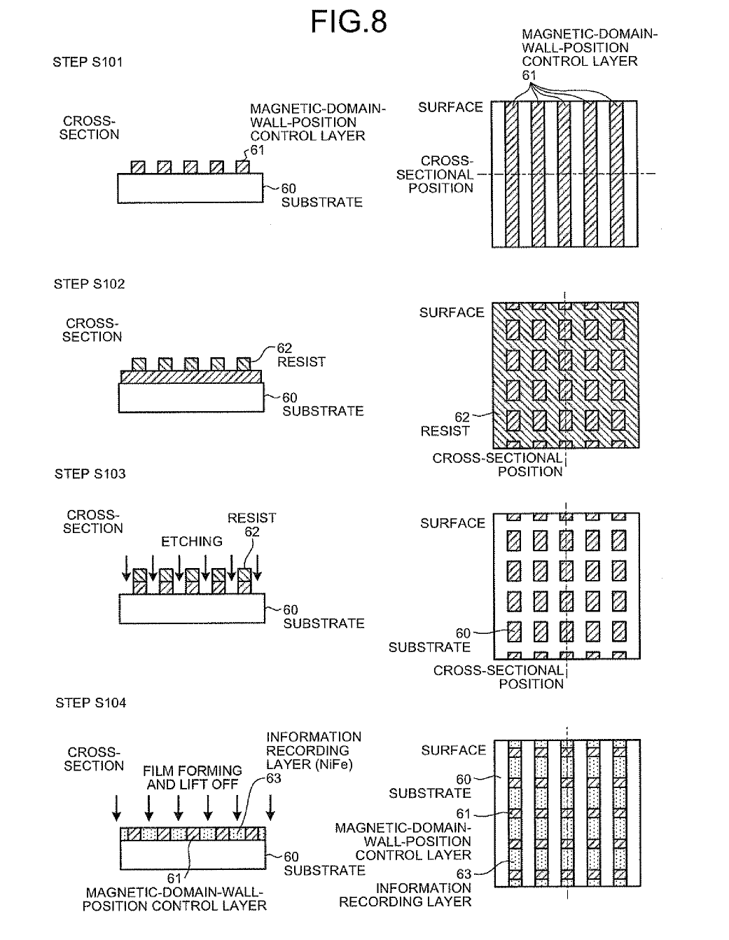

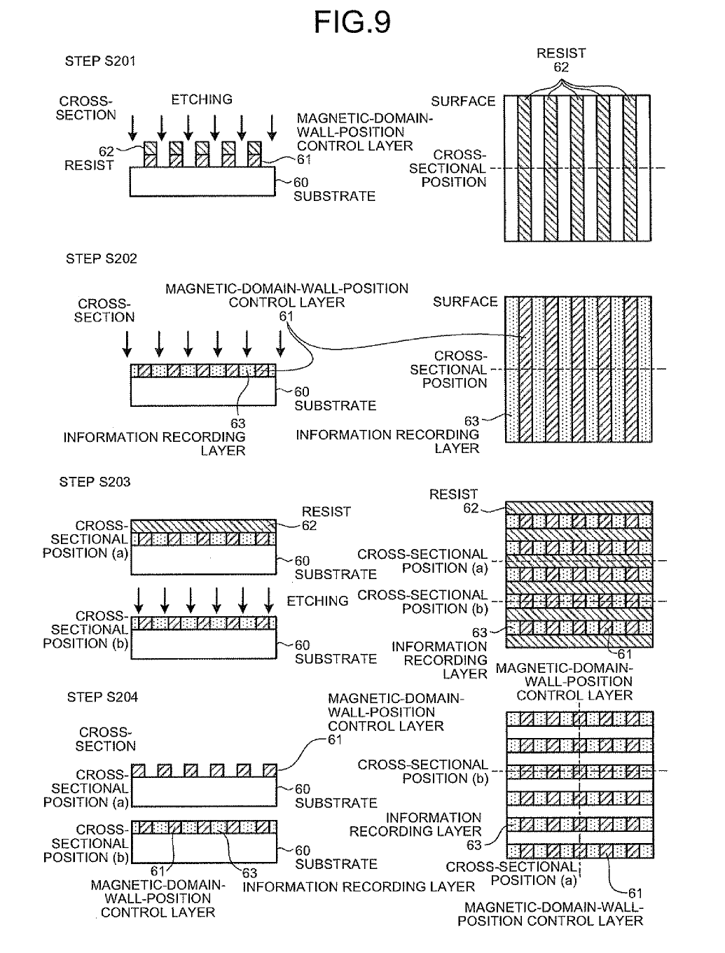

A method of manufacturing the magnetic-domain-wall-motion storage device according to the present embodiment is explained next. FIG. 8 depicts a method of manufacturing the magnetic-domain-wall-motion storage device, and FIG. 9 depicts another method of manufacturing the magnetic-domain-wall-motion storage device.

As illustrated in FIG. 8, a manufacturing device (not illustrated) forms lines of magnetic-domain-wall-position control layers (for example, a magnetic-domain-wall-position control layer corresponds to a NiFe thin line added with an impurity Pt) 61 on a substrate 60 (Step S101) forms resists 62 on the magnetic-domain-wall-position control layers 61, and exposes bit parts of an information recording layer (Step S102).

The manufacturing device then etches the part exposed at Step S102 (Step S103), forms an information recording layer (NiFe, for example) 63 on the etched part, and performs film forming and lift off (Step S104).

Meanwhile, as illustrated in FIG. 9, the manufacturing device forms lines of the magnetic-domain-wall-position control layers 61 on the substrate 60, forms the resists 62 on the magnetic-domain-wall-position control layers 61, exposes the bit parts of an information recording layer, and etches the exposed part (Step S201).

The manufacturing device then forms the information recording layer 63 on the etched part, and performs film forming and lift off (Step S202). The manufacturing device forms the resists 62 in a region other than portions where fine lines are formed, exposes and etches the exposed portions (Step S203), and removes the resists 62 to finally form the memory thin lines (the magnetic-domain-wall-position control layers 61) (Step S204).

As described above, the magnetic-domain-wall-motion storage device according to the present embodiment has ferromagnetic metal thin lines (a NiFePt thin line, for example) adjusted with easiness for a magnetic domain wall to move in a magnetic field, by adding an impurity element (such as Pt, Ir, and W) to the ferromagnetic metal thin lines. Therefore, a position of the magnetic domain wall can be controlled without changing a configuration of the ferromagnetic metal thin line. Accordingly, unpredicted occurrence of magnetization inversion can be prevented.

The magnetic memory element according to the embodiments of the present invention has ferromagnetic metal thin lines adjusted with easiness for a magnetic domain wall to move in a magnetic field, by adding an impurity element to the ferromagnetic metal thin lines. Therefore, a position of the magnetic domain wall can be controlled without changing a configuration of the ferromagnetic metal thin line. Accordingly, unpredicted occurrence of magnetization inversion can be prevented.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

What is claimed is:

1. A magnetic memory element comprising:
an impurity element; and
magnetic thin lines to which the impurity element is added to adjust the movement of a magnetic domain wall in a magnetic field, wherein applying a voltage to the magnetic thin lines controls a position of the magnetic domain wall to invert a magnetization direction of a magnetic recording layer adjacent to the magnetic domain wall, by which information is recorded.

2. The magnetic memory element according to claim 1, wherein the impurity element is an element in which a magnetic holding force of the magnetic thin line is modulated.

3. A magnetic memory device comprising:
an impurity element; and
a magnetic memory element including magnetic thin lines to which the impurity element is added to adjust the movement of a magnetic domain wall in a magnetic field, wherein applying a voltage to the magnetic thin lines controls a position of the magnetic domain wall to invert a magnetization direction of a magnetic recording layer adjacent to the magnetic domain wall, by which information is recorded.

4. The magnetic memory device according to claim 3, wherein the impurity element is an element in which a magnetic holding force of the magnetic thin line is modulated.

5. A method of manufacturing a memory element, comprising:
forming on a substrate, magnetic thin lines to which an impurity element is added to adjust the movement of a magnetic domain wall in a magnetic field; and
forming a recording layer between the magnetic-material thin lines.

6. The method of manufacturing a memory element according to claim 5, wherein the impurity element is an element in which a magnetic holding force of the magnetic thin line is modulated.
